(19) United States
(12) Patent Application Publication
(10) Pub. No.: US 2026/0360659 A1
(43) Pub. Date: Nov. 12, 2026

(54) Pretreatment Method and Charged Particle Beam Device

(71) Applicant: Hitachi High-Tech Corporation, Minato-ku, Tokyo (JP)

(72) Inventors: Shuji KATSUTA, Tokyo (JP); Hiromi MISE, Tokyo (JP); Shuntaro ITO, Tokyo (JP); Yudai KUBO, Tokyo (JP); Kenichi NISHINAKA, Tokyo (JP)

(21) Appl. No.: 19/134,842

(22) PCT Filed: Dec. 8, 2022
(86) PCT No.: PCT/JP2022/045314

§ 371 Date: Jun. 2, 2025

(51) Int. Cl. H01J 37/20; H01J 37/28

(52) U.S. Cl. CPC H01J 37/20; H01J 37/28; H01J 2237/022; H01J 2237/2001

(57) ABSTRACT

An object of the present disclosure is to improve a throughput of a series of steps of TEM observation while preventing an influence of heat due to cleaning in a pretreatment performed before a sample and a transport member are introduced into a charged particle beam device. A pretreatment method according to the present disclosure includes, after cleaning a sample and a transport member on which the sample is mounted by a cleaner and before introducing the sample and the transport member into a charged particle beam device, controlling a temperature of the sample and a temperature of the transport member such that an influence of thermal drift after the sample and the transport member are introduced into the charged particle beam device is less than a threshold (see FIG. 3).

### TECHNICAL FIELD

The present disclosure relates to a method for pretreating a sample and a transport member before introducing the sample into a charged particle beam device.

### BACKGROUND ART

In a semiconductor industry, device miniaturization is further accelerating, and there is an increasing demand for defect analysis and length measurement on a sub-nanometer scale. Accordingly, an increase in demand for scanning transmission electron microscope (STEM)/transmission electron microscope (TEM) observation in which high resolution at an atomic level is obtained by observation with electrons transmitted through a sample is predicted. As the demand for observation increases, automation and speed-up of a series of workflows of TEM observation including pretreatment of the sample are required.

Examples of the pretreatment before the TEM observation include temperature adjustment of an observation sample for the purpose of preventing sample drift due to heat (hereinafter, referred to as thermal drift). When a temperature in a sample chamber in a TEM column and a temperature of the observation sample are different from each other, the thermal drift occurs. In particular, during observation at a high magnification, an influence of the thermal drift becomes remarkable, which affects image quality and accuracy of visual field alignment in automatic observation.

As a method for preventing the thermal drift, a method for waiting until a sample chamber and the observation sample are in a thermal equilibrium state and the thermal drift stops, a method for adjusting the temperature such that the observation sample has the same temperature as the sample chamber, and the like are considered.

Examples of other pretreatments performed before TEM observation include cleaning for the purpose of preventing an occurrence of contamination. This is because the occurrence of sample contamination causes a deterioration in the image quality or a situation under which the observation is difficult. PTL 1 discloses a method for performing cleaning using active oxygen in an accommodation chamber.

### CITATION LIST

### Patent Literature

PTL 1: JP2017-037811A

### SUMMARY OF INVENTION

### Technical Problem

As a cleaning method, a method for emitting UV (ultraviolet), plasma, or an electron beam is known. In common to these methods, after cleaning, a temperature of a sample changes due to a heat from a chemical reaction or a collision of electrons with the sample. Accordingly, it is assumed that cleaning processing is a factor that causes the thermal drift.

In addition, the cleaning for the purpose of preventing the occurrence of contamination and the temperature adjustment for the purpose of preventing the thermal drift both require several minutes to several tens of minutes, which is a problem in improving a throughput of a series of workflows of TEM observation.

The present disclosure has been made in view of the above problems, and an object of the present disclosure is to improve a throughput of a series of steps of TEM observation while preventing an influence of heat due to cleaning in a pretreatment performed before a sample and a transport member are introduced into a charged particle beam device.

### Solution to Problem

A pretreatment method according to the present disclosure includes, after cleaning a sample and a transport member on which the sample is mounted with a cleaner and before introducing the sample and the transport member into a charged particle beam device, controlling a temperature of the sample and a temperature of the transport member such that an influence of thermal drift after the sample and the transport member are introduced into the charged particle beam device is less than a threshold.

### Advantageous Effects of Invention

According to the present disclosure, it is possible to improve a throughput of a series of steps of TEM observation while preventing an influence of heat due to cleaning in a pretreatment performed before a sample and a transport member are introduced into a charged particle beam device.

Problems, configurations, and effects other than those described above will become apparent in the following description of embodiments.

### BRIEF DESCRIPTION OF DRAWINGS

FIG. 1 is a plan view showing a structure of a sample observation system according to Embodiment 1.

FIG. 2 is a side cross-sectional view of FIG. 1.

FIG. 3 is a flowchart showing processing executed by the sample observation system.

FIG. 4 shows a functional block diagram of the sample observation system.

FIG. 5 shows an example of a screen 500 provided by an observation pretreatment control unit 400.

FIG. 6 is a block diagram of a cleaner and temperature coordination control unit 401.

FIG. 7 shows an example of a temporal change in temperature in Embodiment 1.

FIG. 8A shows an example of a temporal change in temperature in Embodiment 2.

FIG. 8B shows an example of the temporal change in temperature in Embodiment 2.

FIG. 9 shows an example of a temporal change in temperature in Embodiment 3.

FIG. 10 shows an example of a temperature change when a cleaner 7 is restarted after being stopped.

### DESCRIPTION OF EMBODIMENTS

Embodiments according to the disclosure will be described in detail with reference to the drawings. In the following embodiments, it is needless to say that a configuration (including steps in a flowchart) is not necessarily essential unless otherwise specified or unless clearly considered to be essential in principle. Hereinafter, preferred embodiments of the present disclosure will be described with reference to the drawings.

In the drawings, the same components are denoted by the same reference numerals in principle, and repeated description thereof is omitted. In order to facilitate understanding of the present disclosure, expressions of components in the drawings may not represent the actual position, size, shape, range, and the like.

For the sake of description, in the case of describing processing executed by a program, a program, a function, a processing unit, and the like may be described as a main body, but a main body of hardware thereof is a processor, or a controller, a device, a computer, a system or the like implemented with a processor. The computer executes processing according to a program read onto a memory by a processor while appropriately using resources such as a memory and a communication interface. Accordingly, a predetermined function, processing unit, and the like are implemented. The processor includes, for example, a semiconductor device such as a central processing unit (CPU) or a graphics processing unit (GPU). The processor is implemented by a device or a circuit capable of performing a predetermined calculation. Processing can be executed not only by software program processing but also by a dedicated circuit. As the dedicated circuit, a field programmable gate array (FPGA), an application specific integrated circuit (ASIC), a complex programmable logic device (CPLD), or the like can be applied.

The program may be installed as data in a target computer in advance, or may be distributed as data from a program source to a target computer and installed. The program source may be a program distribution server on a communication network, or may be a non-transitory computer-readable storage medium (for example, a memory card or a magnetic disk). The program may include a plurality of modules. The computer system may include a plurality of devices. The computer system may be implemented as a cloud computing system or the like.

### Embodiment 1

In the following description of the embodiments, a case in which a cleaner and a device capable of heating and cooling are provided will be described as Embodiment 1, a case in which only the cleaner and a heating device are provided will be described as Embodiment 2, and a case in which only the cleaner serves as the heating device will be described as Embodiment 3.

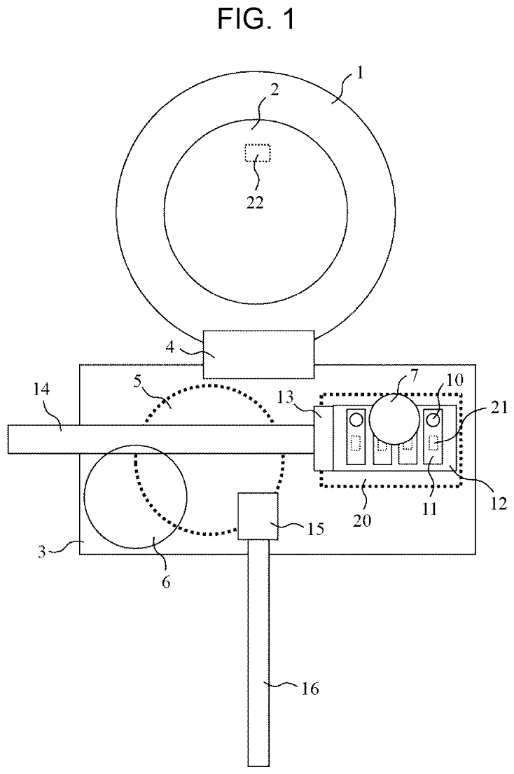

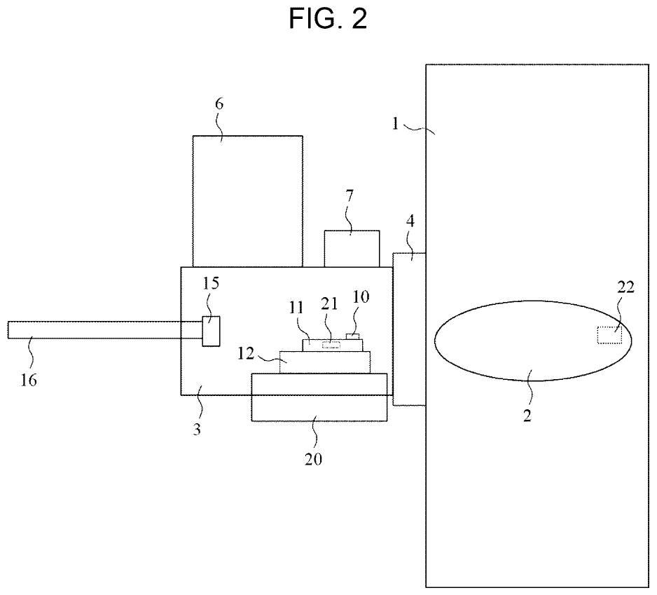

FIG. 1 is a plan view showing a structure of a sample observation system according to Embodiment 1 in the present disclosure. FIG. 2 is a side cross-sectional view of FIG. 1.

A charged particle beam device 1 is, for example, a TEM or a STEM. Here, the TEM and/or the STEM are described as the TEM. The charged particle beam device 1 includes a sample chamber 2.

A load lock chamber 3 is a vacuum preliminary chamber in which a sample waits before observation or after the observation is completed.

A gate valve (charged particle beam device) 4 is a valve that separates the sample chamber 2 from the load lock chamber 3. A gate valve (load lock chamber) 5 is a valve that separates the load lock chamber 3 from an atmosphere.

An evacuation device 6 is a device for evacuating the load lock chamber 3. For example, an ion pump or a turbo molecular pump may be used as the evacuation device 6.

A TEM mesh 10 is a mesh-shaped member in which a plurality of samples can be displaced. Examples of observation target samples being disposed include a thin sample (lamella) processed by a focused ion beam (FIB) processing device or the like. One or more TEM meshes 10 are disposed on a cartridge 11. A plurality of cartridges 11 are disposed on a cassette 12. The cassette 12 is taken in and out of the gate valve (charged particle beam device) 4 to replace the sample. The cassette 12 is gripped by a cassette gripping mechanism 13 and is movable in a lateral direction of FIG. 1 by a cassette transport mechanism 14.

When the sample is loaded into the sample chamber 2, the cartridge 11 is taken out from the cassette 12 using a cartridge gripping mechanism 15. At this time, it is necessary to move the cartridge 11 to be observed to the front of the cartridge gripping mechanism 15 using the cassette transport mechanism 14. When the removal of the cartridge 11 is completed, a cartridge transport mechanism 16 loads the cartridge on a TEM stage. At this time, the cassette 12 is moved using the cassette transport mechanism 14 so as not to interfere with the cassette 12 during loading.

The cleaner 7 is a device that removes contaminants such as hydrocarbons attached to structures such as the TEM mesh 10, the cartridge 11, and a wall surface of the load lock chamber 3. As a method for the cleaner 7, a method for generating active oxygen using UV, a method for emitting an electron beam, or the like can be used.

A sample heating and cooling device 20 (temperature adjustment device) is installed for the purpose of eliminating, by heating or cooling the TEM mesh 10 and the cassette 12, a temperature difference between the sample chamber 2 and the sample (and a temperature difference between the TEM mesh 10 and the sample chamber 2, and a temperature difference between the cassette 12 and the sample chamber 2 when the cassette 12 is introduced into the sample chamber, the same applies hereinafter). A device type suitable as the sample heating and cooling device 20 is determined by a degree of temperature increase of the TEM mesh 10 and the cassette 12 by the cleaner 7, a difference between an internal temperature of the sample chamber 2 and a room temperature, a required observation throughput, and other mechanism design convenience. For example, when both heating and cooling are required, a method using a heat pump used in an air conditioner or a refrigerator, a method using a thermoelectric element such as a Peltier element, or the like is conceivable. In the case of only heating, a method using a heating wire such as a nichrome wire, a method using a non-contact infrared heater, or the like is conceivable. These heating and cooling methods may be combined and implemented. Alternatively, a method for circulating cooling water used to cool a column also to the load lock chamber 3 to bring the cassette 12 into contact therewith is also conceivable. A metal having high thermal conductivity such as copper may be used for an installation surface, the cassette 12, and the cartridge 11. The sample heating and cooling device 20 may be installed inside the cartridge 11, inside the cassette 12, near the cassette gripping mechanism 13, or the like. In any case, the method is not limited as long as the method can prevent the occurrence of thermal drift due to the temperature difference between the inside of the sample chamber 2 and the sample. As in Embodiment 3, the sample heating and cooling device 20 is unnecessary as long as heating for the purpose of preventing drift can be performed only by the cleaner 7.

A sample temperature measurement device 21 is installed for the purpose of measuring a temperature of a sample. It is assumed that the temperature of the TEM mesh 10 and the temperature of the cassette 12 are also measured by measuring the temperature of the sample. As an example, the sample temperature measurement device 21 is installed in the cartridge 11, and an installation location is not limited as long as the temperature can be controlled for the purpose of preventing the occurrence of the thermal drift in each of the sample/the TEM mesh 10/the cassette 12. Either a contact type or a non-contact type may be used. The sample temperature measurement device 21 is not necessarily required as long as a heating time or a cooling time can be determined based on a result of an experiment performed in advance.

A sample chamber temperature measurement device 22 is a device that measures a temperature in the sample chamber 2. When a temperature difference between the temperature of the sample chamber 2 measured in advance and the sample hardly occurs, the temperature in the sample chamber 2 may be treated as a fixed value without using the sample chamber temperature measurement device 22.

### Embodiment 1: Observation Pretreatment Flow

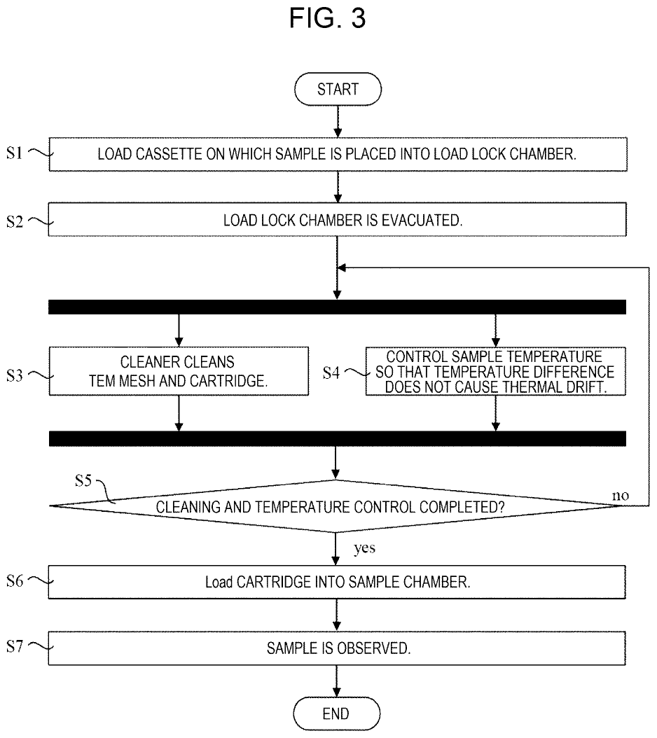

FIG. 3 is a flowchart showing processing executed by the sample observation system. An observation pretreatment flow will be described with reference to FIG. 3.

In step S1, the cassette 12 on which the plurality of cartridges 11 having the TEM mesh 10 mounted on a tip thereof are placed is loaded into the load lock chamber 3. At this time, the cassette 12 is attached to the cassette gripping mechanism 13.

In step S2, the load lock chamber 3 is evacuated. The evacuation is performed using the evacuation device 6 in a state in which the gate valve (load lock chamber) 5 is closed.

Steps S3 and S4 both represent the pretreatment before TEM observation. Steps S3 and S4 are performed simultaneously (in parallel).

In step S3, the cleaner 7 cleans the TEM mesh 10 and the cartridge 11. In order to uniformly clean a plurality of samples without bias, cleaning may be performed while moving the cassette transport mechanism 14.

In step S4, a sample temperature is controlled so that the temperature difference between the sample chamber 2 and the sample falls within a predetermined value at which no thermal drift occurs after the sample is introduced into the sample chamber 2 (the influence of the thermal drift is negligible (less than a threshold)). A start time and an end time of each of S3 and S4 may not be the same, and at least some periods of each step may be performed in parallel. Depending on an observation magnification, the influence of the thermal drift may be sufficiently small, and in such a case, the temperature difference may not be strictly 0, or a temperature allowable error described later may be large. That is, the temperature of each of the sample and the TEM mesh 10 may be adjusted such that the influence of the thermal drift generated after the sample and the TEM mesh 10 are introduced into the sample chamber is at least equal to or less than the threshold level.

In step S5, it is determined whether the cleaning and the temperature adjustment are completed. In the case of the cleaning, the cleaning is completed when a designated time is executed. In the case of the temperature adjustment, it is determined that the temperature adjustment is completed when the temperature difference between the sample chamber 2 and the sample falls within a difference in which the thermal drift is negligible under a magnification and conditions to be observed. When the cleaning and the temperature adjustment are completed, the transport of the cartridge is started in S6.

In step S6, the cartridge gripping mechanism 15 and the cartridge transport mechanism 16 take out the cartridge 11 for which the pretreatment is completed from the cassette 12 and load the cartridge 11 onto a stage of the charged particle beam device 1.

In step S7, the sample on the TEM mesh 10 placed on the cartridge 11 loaded in step S6 is observed.

By performing steps S1 to S7 in the sample observation system, the observation can be performed with a high throughput under a condition in which the contamination or the thermal drift does not occur during observation.

### Embodiment 1: Functional Block Diagram of Sample Observation System

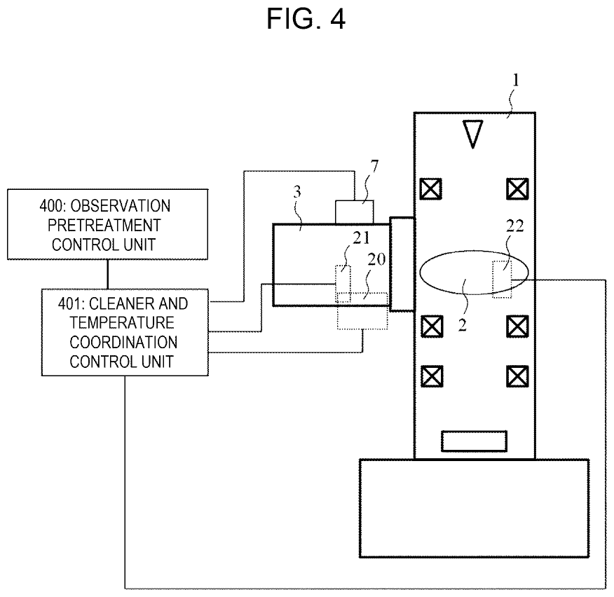

FIG. 4 is a functional block diagram of the sample observation system. The sample observation system includes the charged particle beam device 1, an observation pretreatment control unit 400, and a cleaner and temperature coordination control unit 401.

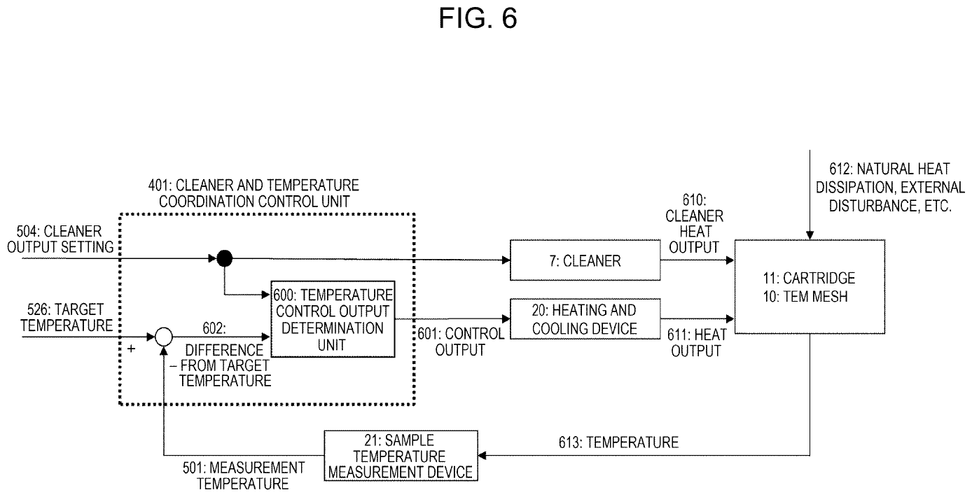

The observation pretreatment control unit 400 sets parameters for an observation pretreatment and instructs execution. The observation pretreatment control unit 400 may be implemented in a computer system in which an operating system (OS) is installed. The observation pretreatment control unit 400 may provide a graphical user interface (GUI) for checking a user operation or a state. Alternatively, the parameter setting and the execution instruction may be automatically performed without assuming a user operation. Details will be described using an example of an operation screen in FIG. 6.

The cleaner and temperature coordination control unit 401 controls an output of the sample heating and cooling device 20 in consideration of the temperature increase of the sample due to the cleaning performed by the cleaner 7. The cleaner and temperature coordination control unit 401 is connected to the cleaner 7 and the sample heating and cooling device 20 to be controlled, and is also connected to the sample temperature measurement device 21. However, the invention is not limited thereto when the sample heating and cooling device 20 is not mounted, such as when a method described in Embodiment 3 to be described later is used. The cleaner and temperature coordination control unit 401 may be mounted in an embedded system that controls an electron microscope such as a lens current. Details of the cleaner and temperature coordination control unit 401 will be described with reference to the block diagram of FIG. 6.

### Embodiment 1: Screen Display of Observation Pretreatment Control Unit

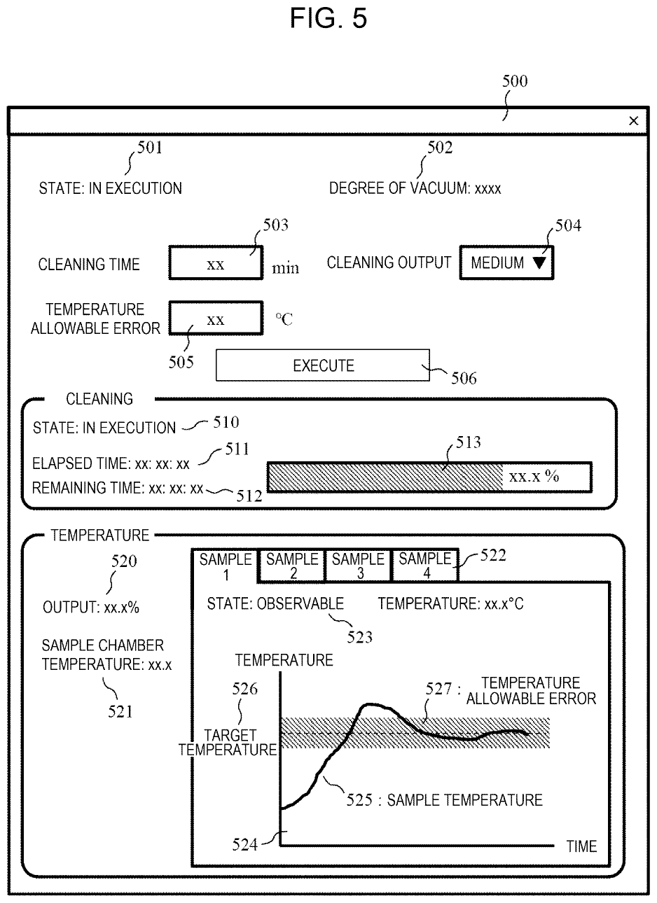

FIG. 5 shows an example of the screen 500 provided by the observation pretreatment control unit 400. The screen 500 is used to describe an example of a behavior of the observation pretreatment control unit 400 in the embodiment, and is not necessarily required to perform pretreatment described in claims.

Reference numeral 501 indicates the state of whether the pretreatment is executable. Examples of the type of the state include an executable state, an in-execution state, and an inexecutable state (such as an evacuation state and an observation state).

Reference numeral 502 indicates a degree of vacuum of the load lock chamber. During the evacuation performed by a user before the pretreatment, it is conceivable to use a waiting time as a guide when waiting for a timing at which the subsequent procedure can be executed.

A text box 503 is used to input a cleaning time, and a combo box 504 is used to select a cleaning output. Since optimum values of the cleaning time and the output vary depending on the type of a sample, the user can change the cleaning time via the text box 503. The cleaning output designates a strength of the output of the cleaner 7. The cleaning time may be selected from the combo box, or the cleaning output may be input in the text box.

A text box 505 is used to input a temperature allowable error. Since the influence of the thermal drift changes depending on a magnification to be observed, a scanning speed at the time of capture, whether to execute energy dispersive X-ray (EDX) observation, and the like, the user can change an allowable error range with respect to a target temperature of the sample.

Reference numeral 506 indicates an execution button. When the execution button is pressed, the cleaning and the temperature adjustment are simultaneously started.

Reference numeral 510 indicates an execution state of cleaning. Examples of a display content include “in execution”, “execution completed”, and “waiting”.

Reference numeral 511 indicates an elapsed time from the start of cleaning, and reference numeral 512 indicates a remaining time of cleaning. The remaining time may be obtained by subtracting the elapsed time from the set cleaning time. A progress bar 513 displays a progress of cleaning.

Reference numeral 520 indicates an output of a heating and cooling device. The output may be displayed in various forms depending on the type of the heating and cooling device.

Reference numeral 521 indicates a temperature of the sample chamber. When there is no special situation, the target temperature during the temperature adjustment is the temperature of the sample chamber 2.

A window 522 displays a temperature of each sample. As an example, the sample temperature measurement device 21 is installed for each sample, but the temperature may not be individually managed for each sample. In the case of the example of FIG. 5, the temperature of which sample is checked can be changed by switching a tab.

Reference numeral 523 indicates a temperature state of the sample. When the temperature is within an allowable error from the target temperature set in 505, a display indicating that the observation is possible is considered, and if not, a display indicating that observation is impossible is considered.

Reference numeral 524 indicates a graph showing a temperature transition of the sample. Reference numeral 525 indicates a time transition of the temperature measured by the sample temperature measurement device 21, reference numeral 526 indicates a target temperature, and reference numeral 527 indicates an allowable error region of the target temperature.

### Embodiment 1: Block Diagram of Cleaner and Temperature Coordination Control Unit 401

FIG. 6 is a block diagram of the cleaner and temperature coordination control unit 401. The present example shows a case in which the output of the sample heating and cooling device 20 can be independently controlled, and the invention is not limited thereto when cooling water in a column is used or when the temperature is adjusted only by the cleaner.

Input values of the block diagram include a cleaner output setting and a target temperature. This corresponds to a value input by the user on the screen in FIG. 5.

A temperature control output determination unit 600 determines a control output 601 to the sample heating and cooling device 20. As a method for determining the output, feedback control using a difference from target temperature 602 may be used, or a temperature increase value may be experimentally obtained from a setting value 504 of the cleaner output, and feedforward control using the result may be performed. The control output may be determined by combining both the feedback control and the feedforward control.

A temperature 613 of the cartridge 11 and the TEM mesh 10 is determined by input values such as a heat output 610 of the cleaner 7, a heat output 611 of the sample heating and cooling device 20, and natural heat dissipation, external disturbance, etc. 612. A measurement result of the temperature 613 by the sample temperature measurement device 21 is a measurement temperature 501.

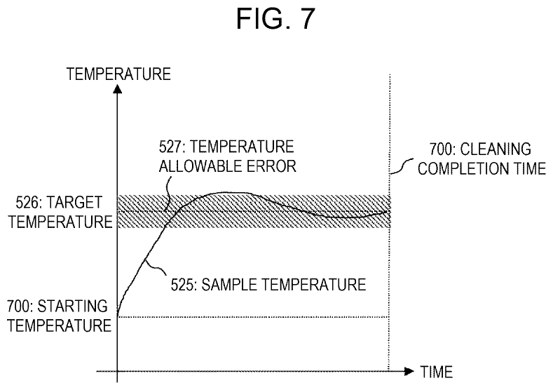

FIG. 7 shows an example of a temporal change in temperature in Embodiment 1. In Embodiment 1, the sample heating and cooling device 20 mainly has a heating function and a cooling function, and FIG. 7 shows an example of a temperature change in that case. By controlling the sample heating and cooling device 20 to follow the target temperature, the temperature increase by the cleaner 7 is reduced, and control is performed so that the temperature adjustment is also completed in a cleaning completion time 700.

### Emboiment 2

In Embodiment 2 of the present disclosure, a case in which the sample heating and cooling device 20 has only a heating function or only a cooling function is assumed as an operation environment. Other configurations are the same as those of Embodiment 1.

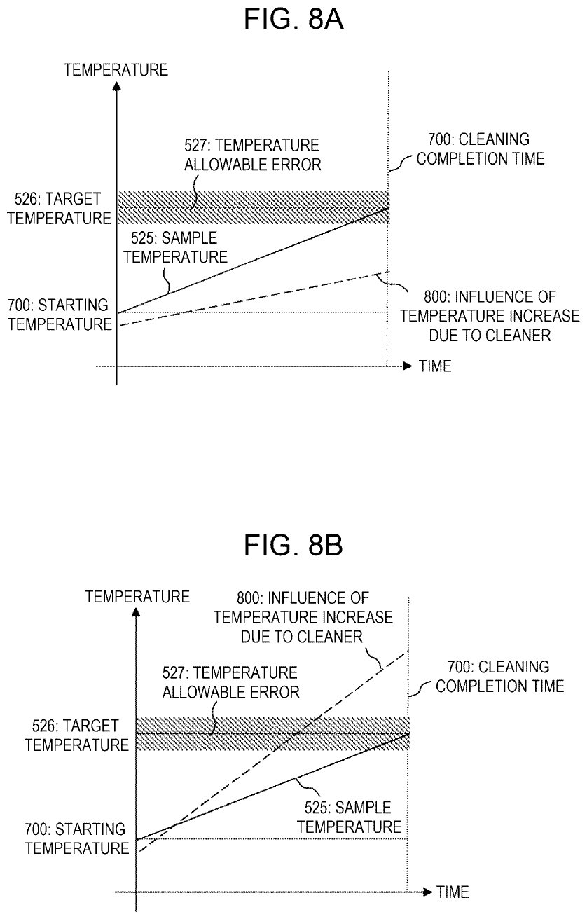

FIG. 8A shows an example of a temporal change in temperature in Embodiment 2. A cleaning operation by the cleaner 7 increases the temperature of the sample, but heat quantity caused by an influence 800 of the temperature increase alone is insufficient to become difficult to reach the target temperature. An insufficient amount of heat is supplemented by the sample heating and cooling device 20, so that the sample can be observed in a state in which the target temperature is reached. In this case, as shown in FIG. 8, a control method for giving the target temperature of the cleaner and temperature coordination control unit 401 in a ramp shape may be used. The temperature increase by the cleaner 7 may be grasped in advance by an experiment or the like.

FIG. 8B shows an example of a temporal change in temperature in Embodiment 2. Unlike FIG. 8A, when the temperature increase due to the cleaning operation by the cleaner 7 is higher than the target temperature, a cooling function of the sample heating and cooling device 20 may be used instead of or in combination with the natural heat dissipation. Cooling is performed in parallel with cleaning.

### Embodiment 3

In Embodiment 3 of the present disclosure, a case in which it is not necessary to use the sample heating and cooling device 20 by using only the cleaner 7 to perform both heating and cleaning of the sample is assumed as an operation environment. Other configurations are the same as those of Embodiment 1.

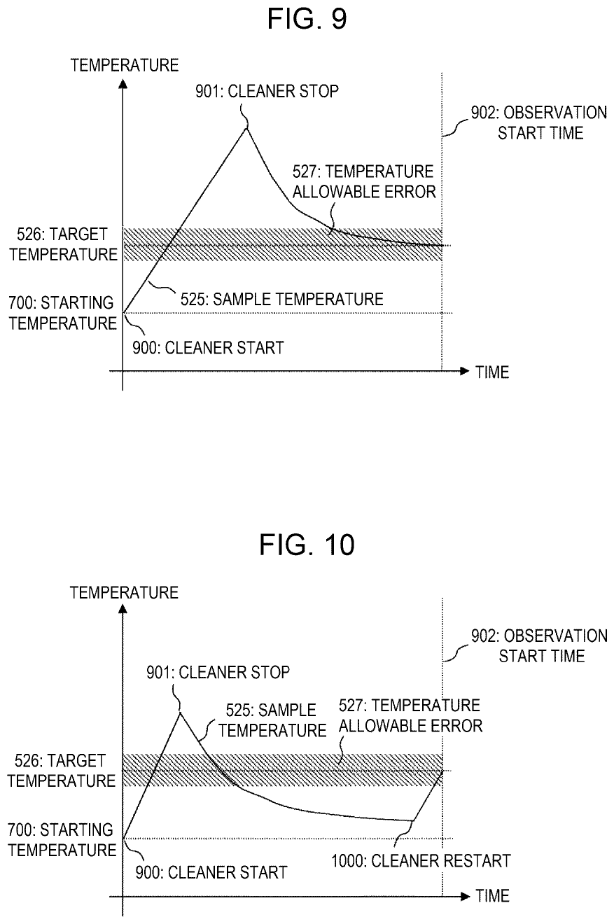

FIG. 9 shows an example of a temporal change in temperature in Embodiment 3. After the cleaner 7 is started, the cleaner 7 is stopped when cleaning for a predetermined time setting is completed. The observation is started when the temperature decreases due to the natural heat dissipation after the stop and reaches the target temperature.

FIG. 10 shows an example of a temperature change when the cleaner 7 is restarted after being stopped. When a plurality of samples in the load lock chamber 3 are observed, the temperature may decrease to below the target temperature depending on an observation order. In this case, as shown in FIG. 10, by restarting and reheating the cleaner 7, observation at the target temperature is possible. However, in this case, since the cleaning is performed a plurality of times, it is necessary to pay attention to prevent excessive cleaning.

### Regarding Modification of Disclosure

In the above embodiments, as the method for holding the sample observed by the charged particle beam device 1 in the load lock chamber 3 and the method for transporting the sample in the load lock chamber 3, those described in FIGS. 1 and 2 are used, but the claims are not limited to the above configuration. Any sample fixing method and any sample transport method may be used as long as the sample to be loaded into the sample chamber 2 and a sample stage for fixing the sample can be pretreated in the load lock chamber 3. That is, the TEM mesh 10, the cartridge 11, the cassette 12, and the like described in the embodiments are merely examples of subordinate concepts of the sample stage for fixing the sample described in the claims.

In the above embodiments, the load lock chamber 3 is a term mainly used in the field of semiconductor manufacturing devices and the like, and refers to a vacuum preliminary chamber intended not to introduce gas molecules, dust, water vapor, and contaminants in the atmosphere into a process chamber. In the present disclosure, for the same purpose, the load lock chamber refers to a vacuum preliminary chamber installed in front of the sample chamber 2 of the charged particle beam device 1.

Depending on the accuracy, an installation form, and the like of the sample temperature measurement device 21, an error may occur in at least one of a measured temperature, an actual temperature of the sample, and an actual temperature of the TEM mesh 10. Therefore, in this case, for example, the temperature allowable error may be increased, or the target temperature may be set to a value different from a sample chamber temperature.

In the above embodiments, the TEM mesh 10 and the cartridge 11 are implemented as transport members capable of mounting a sample and transporting the sample to the sample chamber 2. The target of the present disclosure is not limited thereto, and the present disclosure is also useful in a case in which another type of transport member is used.

In the above embodiments, the observation pretreatment control unit 400 and the cleaner and temperature coordination control unit 401 can be implemented by hardware such as a circuit device in which these functions are implemented, or can be implemented by a calculation device such as a central processing unit (CPU) executing software in which these functions are implemented. These control units can be implemented as a control device that performs the operations of FIGS. 3 and 5 by controlling each unit of the charged particle beam device 1.

In the above embodiments, the thermal drift mainly refers to a change in position due to thermal deformation of the sample or the sample stage. However, the present disclosure is also useful when other problems occur due to a temperature difference.

### REFERENCE SIGNS LIST

1: charged particle beam device
2: sample chamber
3: load lock chamber
4: gate valve (charged particle beam device)
5: gate valve (load lock chamber)
6: evacuation device
7: cleaner
10: TEM mesh
11: cartridge
12: cassette
13: cassette gripping mechanism
14: cassette transport mechanism
15: cartridge gripping mechanism
16: cartridge transport mechanism
20: sample heating and cooling device
21: sample temperature measurement device
22: sample chamber temperature measurement device

1. A pretreatment method for processing a sample and a transport member before the sample and the transport member are introduced to a charged particle beam device that irradiates the sample with a charged particle beam, the transport member on which the sample is mounted being configured to introduce the sample to the charged particle beam device, the method comprising:
a step of cleaning the sample and the transport member using a cleaner configured to remove a contaminant; and
a step of controlling a temperature of the sample and a temperature of the transport member before the transport member on which the sample is mounted is introduced into a sample chamber of the charged particle beam device until an influence of thermal drift of the sample and the transport member after the sample and the transport member are introduced into the sample chamber is equal to or less than a threshold level.

2. The pretreatment method according to claim 1, wherein
the step of controlling the temperature is performed in parallel with the step of cleaning.

3. The pretreatment method according to claim 1, wherein
the step of controlling the temperature includes a step of heating or cooling the sample and the transport member using a temperature adjustment device that performs heating or cooling, and
the step of controlling the temperature is performed by performing the step of cleaning and the step of heating or cooling in parallel.

4. The pretreatment method according to claim 1, wherein
in the step of controlling the temperature, a temperature at which the influence of the thermal drift is equal to or less than the threshold level is set as a target temperature, and
in the step of controlling the temperature, the temperature is controlled based on a difference between an amount of increase in the temperature of the sample caused by the step of cleaning and the target temperature.

5. The pretreatment method according to claim 4, wherein
in the step of controlling the temperature,
the temperature is controlled by performing at least one of
feedback control based on a difference between a result of measuring the temperature of the sample and the target temperature,
feedforward control based on the amount of increase, and
a combination of the feedback control and the feedforward control.

6. The pretreatment method according to claim 1, further comprising:
a step of starting introduction of the transport member into the charged particle beam device when the temperature of the sample and the temperature of the transport member reach a condition that the influence of the thermal drift is equal to or less than the threshold level by the step of cleaning and the step of adjusting the temperature.

7. The pretreatment method according to claim 4, wherein
when the temperature of the sample increased by the amount of increase is lower than the target temperature, in the step of controlling the temperature, a difference between the amount of increase and the target temperature is compensated by heating the sample.

8. The pretreatment method according to claim 4, wherein
when the temperature of the sample increased by the amount of increase is higher than the target temperature, in the step of controlling the temperature, the target temperature is achieved by stopping the cleaner and waiting until the temperature of the sample naturally decreases to the target temperature.

9. The pretreatment method according to claim 8, further comprising:
a step of achieving the target temperature by re-cleaning the sample with the cleaner when the temperature of the sample is lower than the target temperature due to a natural decrease.

10. The pretreatment method according to claim 1, wherein
the cleaner cleans the sample and the transport member using at least one of ultraviolet rays, plasma, or an electron beam.

11. A charged particle beam device for irradiating a sample with a charged particle beam, the device comprising:
a cleaner configured to remove a contaminant;
a sample chamber configured to accommodate a transport member on which the sample is to be mounted;
a transport mechanism configured to transport the transport member; and
a control device configured to control the cleaner and the transport mechanism, wherein
the control device performs
a step of cleaning the sample and the transport member using the cleaner, and
a step of controlling a temperature of the sample and a temperature of the transport member before the transport member on which the sample is mounted is introduced into the sample chamber until an influence of thermal drift of the sample and the transport member after the sample and the transport member are introduced into the sample chamber is equal to or less than a threshold level.

12.The charged particle beam device according to claim 11, wherein
the step of controlling the temperature is performed in parallel with the step of cleaning.

13. The charged particle beam device according to claim 11, wherein
the step of controlling the temperature includes a step of heating or cooling the sample and the transport member using a temperature adjustment device that performs heating or cooling, and
the step of controlling the temperature is performed by performing the step of cleaning and the step of heating or cooling in parallel.

14. The charged particle beam device according to claim 11, wherein
in the step of controlling the temperature, a temperature at which the influence of the thermal drift is equal to or less than the threshold level is set as a target temperature, and
in the step of controlling the temperature, the temperature is controlled based on a difference between an amount of increase in the temperature of the sample caused by the step of cleaning and the target temperature.

15. The charged particle beam device according to claim 14, wherein
in the step of controlling the temperature,
the temperature is controlled by performing at least one of
feedback control based on a difference between a result of measuring the temperature of the sample and the target temperature,
feedforward control based on the amount of increase, and
a combination of the feedback control and the feedforward control.

16. The charged particle beam device according to claim 14, wherein
when the temperature of the sample increased by the amount of increase is lower than the target temperature, in the step of controlling the temperature, a difference between the amount of increase and the target temperature is compensated by heating the sample.

17. The charged particle beam device according to claim 14, wherein
when the temperature of the sample increased by the amount of increase is higher than the target temperature, in the step of controlling the temperature, the target temperature is achieved by stopping the cleaner and waiting until the temperature of the sample naturally decreases to the target temperature.

18. The charged particle beam device according to claim 17, wherein
the control device further performs
a step of achieving the target temperature by re-cleaning the sample with the cleaner when the temperature of the sample is lower than the target temperature due to a natural decrease.

19. The charged particle beam device according to claim 11, wherein
the control device further performs
a step of starting introduction of the transport member into the charged particle beam device when the temperature of the sample and the temperature of the transport member reach a condition that the influence of the thermal drift is equal to or less than the threshold level by the step of cleaning and the step of adjusting the temperature.

20. The charged particle beam device according to claim 11, wherein
the cleaner cleans the sample and the transport member using at least one of ultraviolet rays, plasma, or an electron beam.
